(19) United States
(12) Patent Application Publication
(10) Pub. No.: US 2026/0040837 A1
(43) Pub. Date: Feb. 5, 2026

(54) RESISTIVE RANDOM ACCESS MEMORY AND METHOD OF FORMING THEREOF

(71) Applicant: United Microelectronics Corp., Hsinchu (TW)

(72) Inventors: Shih-Ming Lin, Taipei City (TW); Yang-Ju Lu, Changhua County (TW); Yu-Lung Shih, Tainan City (TW)

(73) Assignee: United Microelectronics Corp., Hsinchu (TW)

(21) Appl. No.: 18/814,606

(22) Filed: Aug. 26, 2024

(30) Foreign Application Priority Data
Aug. 2, 2024 (TW) 113128866

(51) Int. Cl. H10N 70/00; H10B 63/00; H10N 70/20

(52) U.S. Cl. CPC H10N 70/8418; H10B 63/00; H10N 70/011; H10N 70/24; H10N 70/8265

(57) ABSTRACT

A resistive random access memory and a method of forming the same are provided. The resistive random access memory includes a first electrode embedded in a first dielectric layer and having a curved convex top surface, a resistance switch layer on the curved convex top surface of the first electrode, and a second electrode on the resistance switch layer.

### CROSS-REFERENCE TO RELATED APPLICATION

This application claims the priority benefit of Taiwan application serial no. 113128866, filed on Aug. 2, 2024. The entirety of the above-mentioned patent application is hereby incorporated by reference herein and made a part of this specification.

### BACKGROUND

### Technical Field

The disclosure relates to a memory element, and more particularly, to a resistive random access memory (ReRAM) and a method of forming the same.

### Description of Related Art

A main structure of a resistive random access memory includes two layers of upper and lower electrodes and a resistance switch layer therebetween. By controlling a magnitude of a write voltage, a resistance value of stored data is changed to write or erase data.

At present, an explication of a conversion mechanism of the resistive random access memory is mainly based on a filament theory, which is summarized as follows. After the resistive random access memory is manufactured, a large bias voltage is applied to the resistive random access memory first, so that multiple conductive paths similar to filaments are formed inside the resistance switch layer, and currents are conducted through the filaments. Since the currents may be conducted in the resistive random access memory at this time, the resistive random access memory is at a low resistance state (LRS), and this step is called a filament forming step. Then, the bias voltage is used to control compounding of oxygen ions and oxygen vacancies to block the conductive path and enable the resistive random access memory to return from the low resistance state (LRS) to a high resistance state (HRS), and this process is called a reset step. If a voltage smaller than that required in the forming step is applied again, the blocked conductive path may be reconnected, so that the resistive random access memory returns from the high resistance state (HRS) to the low resistance state (LRS) again, and this process is called a set step. If the above set and reset steps are operated repeatedly, writing and erasing of the resistive random access memory may be achieved.

However, the filaments of the resistive random access memory present multiple and unconcentrated distributions in the resistance switch layer, resulting in unstable set and reset operations of elements.

Especially during a manufacturing process, chemical mechanical polishing (CMP) for a bottom electrode of the resistive random access memory often causes a top surface of the bottom electrode to appear in a dishing state after polishing, thereby causing the distribution of the filaments in the resistance switch layer more dispersed, so that the set and reset operations of the resistive random access memory are more unstable.

### SUMMARY

Based on the above issues, the disclosure provides a resistive random access memory and a method of forming the same to solve an issue that filaments of a resistive memory are in multiple and unconcentrated distributions in a resistance switch layer, resulting in unstable set and reset operations.

An embodiment of the disclosure provides a resistive random access memory, including a first electrode embedded in a first dielectric layer and having a curved convex top surface, a resistance switch layer located on the curved convex top surface of the first electrode, and a second electrode located on the resistance switch layer.

In some embodiments, the curved convex top surface is higher than a top surface of the first dielectric layer.

In some embodiments, the curved convex top surface is higher than the top surface of the first dielectric layer by 50 angstroms to 500 angstroms.

In some embodiments, the curved convex top surface is formed by isotropic etching.

In some embodiments, the curved convex top surface is formed by a chemical mechanical polishing process.

In some embodiments, the curved convex top surface is formed by an additional pre-wafer clean process of a chemical mechanical polishing process.

In some embodiments, the resistance switch layer includes a U-shaped structure, and a bottom surface of the U-shaped structure is in contact with the curved convex top surface of the first electrode.

In some embodiments, the resistance switch layer is embedded in a second dielectric layer. The second electrode is embedded in the resistance switch layer. The second dielectric layer is located on the first dielectric layer, and a bottom surface of the second electrode is in contact with a top surface of the resistance switch layer.

An embodiment of the disclosure provides a method of forming a resistive random access memory, including the following. A first electrode layer is formed in a first opening of a first dielectric layer and on a top surface of the first dielectric layer. A removal step is performed to remove the first electrode layer on the top surface of the first dielectric layer to form a first electrode in the first opening. The first electrode has a curved convex top surface. A resistance switch layer is formed on the curved convex top surface of the first electrode. A second electrode is formed on the resistance switch layer.

In some embodiments, the curved convex top surface is higher than the top surface of the first dielectric layer.

In some embodiments, the curved convex top surface is higher than the top surface of the first dielectric layer by 50 angstroms to 500 angstroms.

In some embodiments, the removal step includes isotropic etching to form the curved convex top surface.

In some embodiments, the isotropic etching includes having a higher etching rate for the first dielectric layer than that for the first electrode layer to form the curved convex top surface.

In some embodiments, the removal step includes a chemical mechanical polishing process.

In some embodiments, the chemical mechanical polishing process includes an additional pre-wafer clean processing to form the curved convex top surface.

In some embodiments, the resistance switch layer includes a U-shaped structure, and a bottom surface of the U-shaped structure is in contact with the curved convex top surface of the first electrode.

In some embodiments, forming the resistance switch layer includes the following. A second dielectric layer is formed on the first dielectric layer. The second dielectric layer has a second opening, and the second opening exposes the curved convex top surface of the first electrode. The resistance switch layer is conformally formed in the second opening and on the second dielectric layer.

Based on the above, the disclosure provides the resistive random access memory, enabling the filaments to be concentrated and enabling the set and reset operations to be more stable, so as to improve stability of the overall resistive random access memory.

In addition, the method of forming the resistive random access memory provided in the disclosure does not require other added process steps or complex processes. It is only required to adjust a recipe design of the original removal step to obtain a specific electrode outline, enabling the filaments to be more concentrated to improve the stability of the overall resistive random access memory.

In order for the aforementioned features and advantages of the disclosure to be more comprehensible, embodiments accompanied with drawings are described in detail below.

### BRIEF DESCRIPTION OF THE DRAWINGS

FIGS. 1 to 6 are schematic cross-sectional views of a method of forming a resistive random access memory according to an embodiment of the disclosure.

### DETAILED DESCRIPTION OF DISCLOSED EMBODIMENTS

The disclosure will be described in detail with reference to the drawings of the embodiments. However, the disclosure may also be implemented in various different forms and shall not be limited to the embodiments described herein. Sizes and distances of polygons in the drawings are drawn for visual clarity and are not the original sizes and distances. The same or similar elements will be denoted by the same or similar reference numerals, and repeated description thereof will be omitted in the following embodiments.

As used herein, “connection” may refer to physical and/or electrical connection, while “electrical connection” or “coupling” may be that there is another element between two elements.

The term “about”, “approximately”, or “substantially” used herein includes the value and an average value within an acceptable deviation range of specific values determined by a person of ordinary skill in the art, taking into account discussed measurements and a specific number of measurement-related errors (i.e., limitations of a measuring system). For example, the term “about” may mean being within one or more standard deviations of the value, or within, for example, ±30%, ±20%, ±10%, and ±5%. Moreover, the term “about”, “approximately”, or “substantially” used herein may mean selecting a more acceptable deviation range or standard deviations according to optical properties, etching properties, or other properties, without applying a single standard deviation to all properties.

The terms used herein are used to merely describe exemplary embodiments and are not used to limit the present disclosure. In this case, unless indicated in the context specifically, otherwise the singular forms include the plural forms.

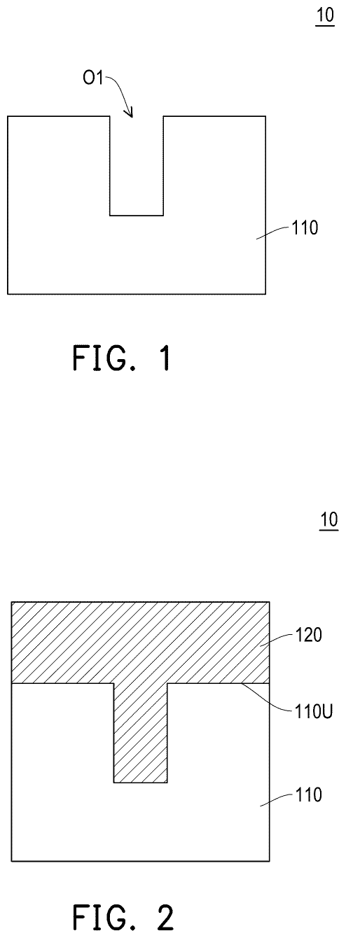

FIGS. 1 to 6 are schematic cross-sectional views of a method of forming a resistive random access memory according to an embodiment of the disclosure.

As shown in FIG. 1, a first dielectric layer 110 is provided, and a first opening O1 may be formed in the first dielectric layer 110 through various patterning processes, such as photolithography etching.

The first dielectric layer 110 may be formed by various dielectric materials, such as silicon oxide, fluorinated silica glass (FSG), phosphosilicate glass (PSG), borophosphosilicate glass (BPSG), carbon doped silicon oxide (SiOxCy), Black Diamond® (applied materials of Santa Clara, Calif.), xerogel, aerogel, amorphous fluorinated carbon, parylene, bis-benzocyclobutenes (BCB), SiLK (a commercial product of Dow Chemical Co.), polyimide, and/or other dielectric materials developed in the future.

Next, as shown in FIG. 2, a first electrode layer 120 is formed in the first opening O1 of the first dielectric layer 110 and on a top surface 110U of the first dielectric layer 110.

The first electrode layer 120 may include various conductive materials, such as gold (Au), platinum (Pt), ruthenium (Ru), iridium (Ir), titanium (Ti), aluminum (Al), copper (Cu), tantalum (Ta), tungsten (W), or alloys thereof, but the disclosure is not limited thereto.

In some embodiments, the first electrode layer 120 may be formed in the first opening O1 of the first dielectric layer 110 and on the top surface 110U of the first dielectric layer 110 by using chemical vapor deposition (CVD) or physical vapor deposition (PVD), but the disclosure is not limited thereto.

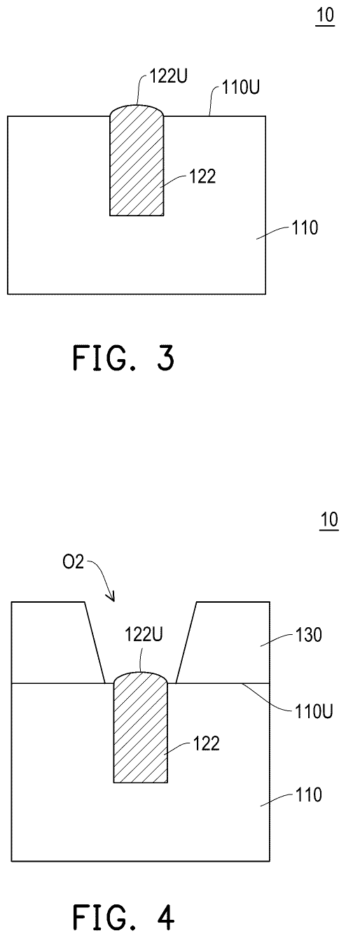

Next, as shown in FIG. 3, a removal step is performed to remove the first electrode layer 120 on the top surface 110U of the first dielectric layer 110, so as to form a first electrode 122 embedded in the first dielectric layer 120 in the first opening O1 and expose a curved convex top surface 122U thereof. The first electrode 122 may serve as a bottom electrode of a resistive random access memory 10.

In some embodiments, the above removal step may include various isotropic etchings, so as to remove the first electrode layer 120 on the top surface 110U of the first dielectric layer 110 and form the curved convex top surface 122U of the first electrode 122. That is, the curved convex top surface 122U of the first electrode 122 may be formed by various isotropic etchings.

In some embodiments, the isotropic etching may include wet etching.

In some embodiments, the isotropic etching may include an etching process with a higher etching rate for the first dielectric layer 110 than that for the first electrode layer 120, so as to form the curved convex top surface 122U of the first electrode 122, and enable the curved convex top surface 122U of the first electrode 122 to slightly protrude from the top surface 110U of the first dielectric layer 110, as shown in FIG. 3. That is, the curved convex top surface 122U of the first electrode 122 is higher than the top surface 110U of the first dielectric layer 110 by about 50 angstroms to about 500 angstroms. An etching rate ratio of the first dielectric layer 110/the first electrode layer 120 depends on materials used. For example, an etching rate ratio of using silicon oxide as the first dielectric layer 110/using tungsten as the first electrode layer 120 is approximately greater than 10/1, but the disclosure is not limited thereto.

In some embodiments, the removal step may include chemical mechanical polishing.

In some embodiments, the curved convex top surface 122U of the first electrode 122 may be formed by a chemical mechanical polishing process.

In some embodiments, since a process of embedding the first electrode 122 having the curved convex top surface 122U into the first dielectric layer 120 includes a step of removing a large range of the first electrode layer 120 from the top surface 110U of the first dielectric layer 110, this comprehensive planarization may be accomplished by the chemical mechanical polishing. Moreover, in addition to grinding particles, a polishing liquid in the chemical mechanical polishing also includes various etching liquids that function similarly to the wet etching, so that while mechanical polishing and removing is performed, the removal step is also performed by using chemical wet etching.

Therefore, for example, when the first electrode layer 120 is polished until the top surface 110U of the first dielectric layer 110 is about to be exposed, referring to FIGS. 2 and 3, by adjusting composition of the polishing liquid, the polishing liquid at this time has a higher etching rate for the first dielectric layer 110 than that for the first electrode layer 120, so as to form the curved convex top surface 122U of the first electrode 122. That is, the curved convex top surface 122U of the first electrode 122 may be accomplished by adjusting the composition of the polishing fluid in the chemical mechanical polishing process.

In addition to forming the curved convex top surface 122U of the first electrode 122 by adjusting the composition of the polishing fluid, in some embodiments, an additional pre-wafer clean processing may also be added before a main polishing step in the chemical mechanical polishing process is performed. The pre-wafer clean processing may protect the first electrode layer 120, so that the first electrode 122 embedded in the first dielectric layer 120 has the curved convex top surface 122U after the subsequent main polishing step.

That is to say, the curved convex top surface 122U of the first electrode 122 may also be formed by the additional pre-wafer clean processing in the chemical mechanical polishing process.

Therefore, the method of forming the resistive random access memory provided in the disclosure does not require other added process steps or complex processes. It is only required to adjust a recipe design of the original removal step to obtain a specific electrode outline, enabling filaments to be more concentrated to improve stability of the overall resistive random access memory.

Next, a resistance switch layer 140 is formed on the curved convex top surface 122U of the first electrode 122.

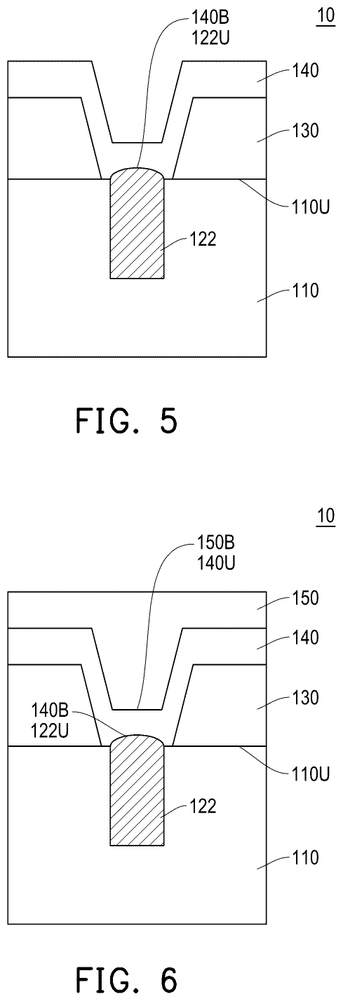

In addition, the resistance switch layer 140 may be formed on the curved convex top surface 122U of the first electrode 122 in various forms. For example, it is formed on the curved convex top surface 122U of the first electrode 122 in a block shape, or the resistance switch layer 140 including a U-shaped structure as described below is formed on the convex top surface 122U of the first electrode 122, and a bottom surface 140B of the U-shaped structure thereof is in contact with the curved convex top surface 122U of the first electrode 122, as shown in FIG. 5.

Referring to FIG. 4, a second dielectric layer 130 is formed on the first dielectric layer 110, and a second opening O2 is formed in the second dielectric layer 130 through various patterning processes, such as photolithography etching. The second opening O2 exposes the curved convex top surface 122U of the first electrode 122.

In some embodiments, the second dielectric layer 130 may be formed by the same or different materials than the first dielectric layer 110. In addition, as the first dielectric layer 110, the second dielectric layer 130 may be formed by various dielectric materials, such as silicon oxide, fluorinated silica glass (FSG), phosphosilicate glass (PSG), borophosphosilicate glass (BPSG), carbon doped silicon oxide (SiOxCy), Black Diamond® (applied materials of Santa Clara, Calif.), xerogel, aerogel, amorphous fluorinated carbon, parylene, bis-benzocyclobutenes (BCB), SiLK (a commercial product of Dow Chemical Co.), polyimide, and/or other dielectric materials developed in the future.

Next, referring to FIG. 5, the resistance switch layer 140 is conformally formed in the second opening O2 of the second dielectric layer 130 and on the second dielectric layer 130. That is, the resistance switch layer 140 is formed on the curved convex top surface 122U of the first electrode 122, and the resistance switch layer 140 is embedded in the second dielectric layer 130.

The resistance switch layer 140 has resistance switching characteristics. That is, a resistance thereof changes according to an applied voltage.

The resistance switch layer 140 may include a dielectric layer and become a conductor or an insulator according to the applied voltage.

In some embodiments, the resistance switch layer 140 may include transition metal oxides, such as NiO, TiO₂, HfO, ZrO, ZnO, WO₃, CoO, Nb₂O₅, Fe₂O₃, CuO, CrO₂, SrZrO₃, and/or others resistance switching materials developed in the future.

In some embodiments, the resistance switch layer 140 may be conformally formed in the second opening O2 of the second dielectric layer 130 and on the second dielectric layer 130 by processes such as chemical vapor deposition (CVD), physical vapor deposition (PVD), and atomic layer deposition (ALD), but the disclosure is not limited thereto. That is, the resistance switch layer 140 is formed on the curved convex top surface 122U of the first electrode 122.

Next, a second electrode 150 is formed on the resistance switch layer 140.

As shown in FIG. 6, if the resistance switch layer 140 is the above resistance switch layer 140 including the U-shaped structure, the second electrode 150 may be embedded in the U-shaped structure of the resistance switch layer 140. A bottom surface 150B of the second electrode 150 is in contact with a top surface 140U of the resistance switch layer 140. The second electrode 150 may serve as a top electrode of the resistive random access memory 10.

In some embodiments, the second electrode 150 may include various conductive materials as the above first electrode 122, such as gold (Au), platinum (Pt), ruthenium (Ru), iridium (Ir), titanium (Ti), aluminum (Al), copper (Cu), tantalum (Ta), tungsten (W), or alloys thereof.

In an embodiment, the second electrode 150 may be formed by different materials from the first electrode 122. For example, the first electrode 122 is formed by tungsten (W), and the second electrode 150 is formed by copper (Cu). In another embodiment, the second electrode 108 may be formed by the same material as the first electrode 104.

In some embodiments, the second electrode 150 may be formed on the top surface 140U of the resistance switch layer 140 by using methods such as chemical vapor deposition (CVD), physical vapor deposition (PVD), and spin-on coating. However, the disclosure is not limited thereto.

The first electrode 122 and the second electrode 150 may be connected to various interconnection structures (not shown) to operate or read the resistive random access memory 10 and enable it to transmit or receive signals with other circuits and/or active devices.

Through the method of forming the resistive random access memory provided in the disclosure, it is only required to adjust the recipe design in the step of removing the redundant first electrode layer to form the first electrode. Without additional process steps or complex processes, an electrode structure with the curved convex top surface may be obtained, enabling the filaments to be more concentrated and allowing the set and reset operations of the resistive random access memory to be more stable to improve the stability of the overall element.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A resistive random access memory, comprising:
a first electrode embedded in a first dielectric layer and having a curved convex top surface;
a resistance switch layer located on the curved convex top surface of the first electrode; and
a second electrode located on the resistance switch layer.

2. The resistive random access memory according to claim 1, wherein the curved convex top surface is higher than a top surface of the first dielectric layer.

3. The resistive random access memory according to claim 2, wherein the curved convex top surface is higher than the top surface of the first dielectric layer by 50 angstroms to 500 angstroms.

4. The resistive random access memory according to claim 1, wherein the curved convex top surface is formed by isotropic etching.

5. The resistive random access memory according to claim 1, wherein the curved convex top surface is formed by a chemical mechanical polishing process.

6. The resistive random access memory according to claim 1, wherein the curved convex top surface is formed by an additional pre-wafer clean process of a chemical mechanical polishing process.

7. The resistive random access memory according to claim 1, wherein the resistance switch layer comprises a U-shaped structure, wherein a bottom surface of the U-shaped structure is in contact with the curved convex top surface of the first electrode.

8. The resistive random access memory according to claim 7, wherein
the resistance switch layer is embedded in a second dielectric layer; and
the second electrode is embedded in the resistance switch layer, wherein
the second dielectric layer is located on the first dielectric layer, and
a bottom surface of the second electrode is in contact with a top surface of the resistance switch layer.

9. A method of forming a resistive random access memory, comprising:
forming a first electrode layer in a first opening of a first dielectric layer and on a top surface of the first dielectric layer;
performing a removal step to remove the first electrode layer on the top surface of the first dielectric layer to form a first electrode in the first opening, wherein the first electrode has a curved convex top surface;
forming a resistance switch layer on the curved convex top surface of the first electrode; and
forming a second electrode on the resistance switch layer.

10. The method of forming the resistive random access memory according to claim 9, wherein the curved convex top surface is higher than the top surface of the first dielectric layer.

11. The method of forming the resistive random access memory according to claim 10, wherein the curved convex top surface is higher than the top surface of the first dielectric layer by 50 angstroms to 500 angstroms.

12. The method of forming the resistive random access memory according to claim 9, wherein the removal step comprises isotropic etching to form the curved convex top surface.

13. The method of forming the resistive random access memory according to claim 12, wherein the isotropic etching comprises having a higher etching rate for the first dielectric layer than that for the first electrode layer to form the curved convex top surface.

14. The method of forming the resistive random access memory according to claim 9, wherein the removal step comprises a chemical mechanical polishing process.

15. The method of forming the resistive random access memory according to claim 14, wherein the chemical mechanical polishing process comprises an additional pre-wafer clean processing to form the curved convex top surface.

16. The method of forming the resistive random access memory according to claim 9, wherein the resistance switch layer comprises a U-shaped structure, wherein a bottom surface of the U-shaped structure is in contact with the curved convex top surface of the first electrode.

17. The method of forming the resistive random access memory according to claim 16, wherein forming the resistance switch layer comprises:
forming a second dielectric layer on the first dielectric layer, wherein the second dielectric layer has a second opening, and the second opening exposes the curved convex top surface of the first electrode; and
conformally forming the resistance switch layer in the second opening and on the second dielectric layer.
